(19) United States
(12) Patent Application Publication
(10) Pub. No.: US 2026/0344501 A1
(43) Pub. Date: Oct. 29, 2026

(54) SJ Semiconductor(Jiangyin) Corporation

(71) Applicant: SJ Semiconductor(Jiangyin) Corporation, Jiangyin (CN)

(72) Inventors: Yenheng CHEN, Jiangyin (CN); Chengchung LIN, Jiangyin (CN); Jin YANG, Jiangyin (CN)

(73) Assignee: SJ Semiconductor(Jiangyin) Corporation, Jiangyin, JS (CN)

(21) Appl. No.: 19/114,471

(22) PCT Filed: Jun. 8, 2023
(86) PCT No.: PCT/CN2023/099211

§ 371 Date: Mar. 24, 2025

(30) Foreign Application Priority Data
Sep. 26, 2022 (CN) 202211175328.8

(51) Int. Cl. H10W 74/01; C25D 7/12; H10W 40/20; H10W 42/00; H10W 70/05; H10W 70/685; H10W 80/00

(52) U.S. Cl. CPC H10W 74/019; C25D 7/123; H10W 40/235; H10W 42/121; H10W 70/05; H10W 70/685; H10W 80/00

(57) ABSTRACT

An integrated circuit package structure and manufacturing method are disclosed; the package structure includes: an RDL, including a first surface in contact with the substrate and a second surface opposite to the first surface, wherein the RDL includes a first sub RDL and a second sub RDL stacked on top of each other; the RDL is made of photosensitive dry film dielectric layers and plated metal interconnects; an encapsulation layer, covering the chips and the RDL; a heat sink cover over the substrate, enclosing the encapsulation layer, chips, and the encapsulation layer. The multiple chips with different functions are integrated in a single package structure, improving the integration of the package. The adoption of high-resolution dry film dielectric layers enables forming a fine RDL structure, increasing the bandwidth of the final device and decreasing inter-chip delays. Therefore, high-density wiring capability is achieved without TSV-containing interposers, thus lowering production cost.

### FIELD OF THE INVENTION

The present disclosure relates to the field of semiconductor packaging, and in particular relates to an integrated circuit package structure and a manufacturing method.

### BACKGROUND OF THE INVENTION

The semiconductor integrated circuit (IC) industry has experienced rapid development. Packaging, a crucial part of IC manufacturing, significantly impacts the performance of the chip itself. It not only serves to place, fix, seal, and protect the chip, and enhances its electrical and thermal properties, but also provides the electrical connection between bonding points inside the IC chip and the outside contacts.

With the increased users' demand for advanced functions, the desire for large bandwidth (the ability to process signals at high speed) in mobile communication products is also growing. The main factors affecting the bandwidth include the I/O density in the packaging system and the line width/spacing (L/S) in the redistribution layer (RDL). Currently, a common solution is to package memory chips and processor chips together through packaging processes to achieve device miniaturization. However, for high-density I/O and low L/S packaging structures, core technologies such as the Through-Silicon Vias (TSVs) are generally applied. These core technologies are costly, and the process of forming high-density I/O packaging structures is difficult, which reduces bandwidth and increases latency between chips. Therefore, it is necessary to improve the above-described packaging process.

### SUMMARY OF THE INVENTION

The present disclosure provides an integrated circuit package structure and a manufacturing method thereof, for solving the problems of low bandwidth, high inter-chip latency, and high packaging cost in packaging technologies.

The disclosed manufacturing method includes:
forming a release layer on a temporary substrate;
forming an RDL on the release layer, wherein the RDL includes a first sub RDL and a second sub RDL stacked on top of each other, using photosensitive dry film dielectric layers and a copper layer from dual damascene process, the RDL includes a first surface in contact with the release layer and a second surface opposite to the first surface;
bonding chips to the second surface of the RDL, wherein the chips are electrically connected to the RDL;
forming an encapsulation layer covering the chips and the RDL;
removing the temporary substrate and the release layer to reveal the first surface of the RDL; and
bonding a substrate to the first surface of the RDL and electrically connecting the substrate to the RDL.

Optionally, the first sub RDL is formed by:
forming a first photosensitive dry film dielectric layer over the release layer, photo-etching the first photosensitive dry film dielectric layer to form first openings;
forming a second photosensitive dry film dielectric layer over the first photosensitive dry film dielectric layer, photo-etching the second photosensitive dry film dielectric layer to form second openings, and the second openings are communicated with the first openings;
forming a Ti/Cu seed layer over the second photosensitive dry film dielectric layer, the first openings, and the second openings; and
forming a plating layer over the Ti/Cu seed layer through electroplating and planarizing the plating layer.

Optionally, a first metal wiring portion is formed in the first sub RDL, a second metal wiring portion is formed in the second sub RDL, and the first metal wiring portion is electrically connected to the second metal wiring portion along a vertical direction.

Optionally, the method further includes forming a heat sink cover over the substrate or forming a reinforcing member over the substrate.

Optionally, the chips include a first chip and second chips, and the second chips are symmetrically arranged on two sides of the first chip, the first chip includes a logic chip, and the second chips include memory chips.

Optionally, after the encapsulation layer is formed the encapsulation layer is planarized to expose top surfaces of the chips.

The present disclosure also provides an integrated circuit package structure, including: a substrate; an RDL, including a first surface in contact with the substrate and a second surface opposite to the first surface, wherein the RDL is made of photosensitive dry film dielectric layers, and the RDL includes a first sub RDL and a second sub RDL stacked on top of each other; chips, wherein the chips are disposed over the second surface of the RDL and electrically connected to the RDL; and an encapsulation layer, covering the chips and the RDL.

Optionally, a thickness of the first sub RDL ranges from 1 to 20 μm and a thickness of the second sub RDL ranges from 1 to 20 μm.

Optionally, a first metal wiring portion is formed in the first sub RDL, a second metal wiring portion is formed in the second sub RDL, and the first metal wiring portion is electrically connected to the second metal wiring portion along a vertical direction.

Optionally, the structure further includes a heat sink cover over the substrate, wherein the heat sink cover covers the encapsulation layer and is mechanically connected to the substrate or a reinforcing member over the substrate, wherein the reinforcing member has a height taller than a surface of the encapsulation layer and is mechanically connected to the substrate.

The presently disclosed integrated circuit package structure and the manufacturing method have the following beneficial effects: a plurality of chips with different functions are integrated in a single package structure to improve the integration level of the package; the adoption of high-resolution dry film polymer enables forming a finer RDL structures so as to increase the bandwidth of the final device and decrease inter-chip delay. Thus, high-density wiring capability is achieved without TSV-containing interposers and production cost is lowered.

### BRIEF DESCRIPTION OF DRAWINGS

FIG. 1 is a flowchart illustrating a manufacturing method of an integrated circuit package structure according to an embodiment of the present disclosure.

FIG. 2 is a cross-sectional view of an intermediate structure obtained after a release layer is formed over a temporary substrate according to an embodiment of the present disclosure.

FIG. 3 is a cross-sectional view of an intermediate structure obtained after a first photosensitive dry film dielectric layer is formed according to an embodiment of the present disclosure.

FIG. 4 is a cross-sectional view of an intermediate structure obtained after a second photosensitive dry film dielectric layer is formed according to an embodiment of the present disclosure.

FIG. 5 is a cross-sectional view of an intermediate structure obtained after a plating layer is formed according to an embodiment of the present disclosure.

FIG. 6 is a cross-sectional view of an intermediate structure obtained after the plating layer is planarized according to an embodiment of the present disclosure.

FIG. 7 is a cross-sectional view of an intermediate structure obtained after a second sub RDL is formed according to an embodiment of the present disclosure.

FIG. 8 is a cross-sectional view of an intermediate structure obtained after chips are provided on the RDL according to an embodiment of the present disclosure.

FIG. 9 is a cross-sectional view of an intermediate structure obtained after an encapsulation layer is formed over the chips according to an embodiment of the present disclosure.

FIG. 10 is a cross-sectional view of an intermediate structure obtained after the encapsulation layer is thinned according to an embodiment of the present disclosure.

FIG. 11 is a cross-sectional view of an intermediate structure obtained after removal of the temporary substrate and release layer according to an embodiment of the present disclosure.

FIG. 12 is a cross-sectional view of an intermediate structure obtained after the substrate bonding according to an embodiment of the present disclosure.

FIG. 13 is a cross-sectional view of a package structure obtained after a heat sink cover is formed according to an embodiment of the present disclosure.

FIG. 14 is a cross-sectional view of another package structure according to an embodiment of the present disclosure.

### REFERENCE NUMERALS

101 Temporary Substrate
102 Release Layer
103 Redistribution Layer
1031 First Surface
1032 Second Surface
104 First Sub RDL
1041 First Photosensitive Dry Film Dielectric Layer
1042 Second Photosensitive Dry Film Dielectric Layer
1043 First Openings
1044 Second Openings
1045 First Metal Wiring Portion
1046 Second Metal Wiring Portion
105 Second Sub RDL
106 Chips
1061 First Chip
1062 Second Chips
107 Encapsulation Layer
108 Substrate;
109 Heat Sink Cover
110 Reinforcing Member
S1~S6 Various Manufacturing Steps

### DETAILED DESCRIPTION

The embodiments of the present disclosure will be described below. Those skilled can easily understand advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

For the convenience of description, spatial relation terms such as “below”, “under”, “beneath”, “on”, “above”, “up”, etc. may be used herein to describe the relationships between an element or feature and other elements or features. It will be understood that these spatial relationship terms are intended to encompass directions/orientations of the device in use or operation other than those depicted in the drawings. In addition, when a first layer is referred to as being “between” a second layer and a third layer, the first layer may be the only layer between the second and third layers, or there may more layers between the two layers.

It is to be understood that the use of terms such as “first” and “second” to components is solely for the purpose of distinguishing between the aforementioned components. Unless otherwise stated, these terms do not carry any other special meaning and should not be interpreted as restricting the scope of the present disclosure.

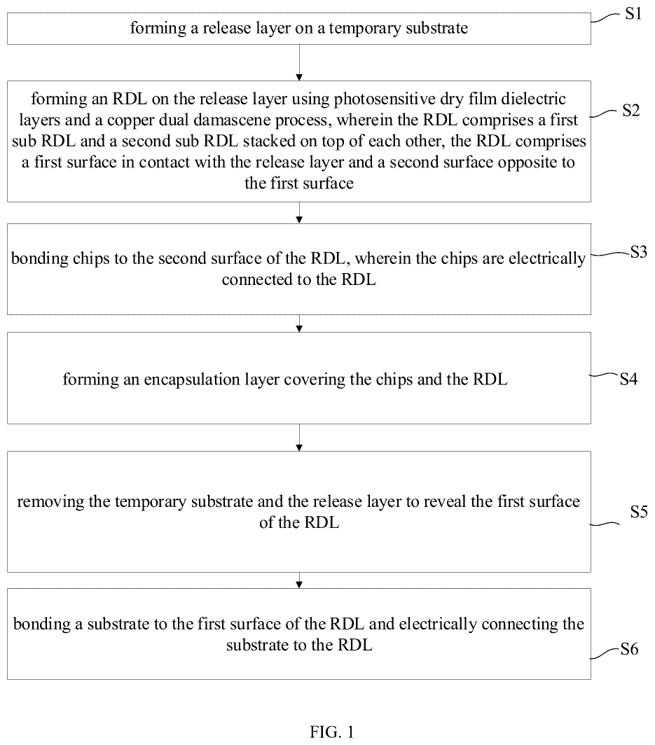

Refer to FIGS. 1-14. It should be noted that the drawings provided in this disclosure only illustrate the basic concept of the present disclosure in a schematic way, so the drawings only show the components closely related to the present disclosure. The drawings are not necessarily drawn according to the number, shape, and size of the components in actual implementation; during the actual implementation, the type, quantity, and proportion of each component can be changed as needed, and the components' layout may also be more complicated.

### Embodiment 1

Referring to FIGS. 1 to 14, the present disclosure provides a manufacturing method of an integrated circuit package structure, wherein the method includes S1-S6:
S1: providing a temporary substrate 101, forming a release layer 102 on the temporary substrate 101;
S2: forming an RDL 103 on the release layer 102, involving disposing photosensitive dry film dielectric layers and a copper layer from dual damascene process, wherein the RDL 103 includes a first sub RDL 104 and a second sub RDL 105 stacked on top of each other, the RDL 103 has a first surface 1031 in contact with the release layer 102 and a second surface 1032 opposite to the first surface 1031;
S3: bonding chips 106 to the second surface 1032 of the RDL 103, wherein the chips 106 are electrically connected to the RDL 103;
S4: forming an encapsulation layer 107 covering the chips 106 and the RDL 103;
S5: removing the temporary substrate 101 and the release layer 102 to reveal the first surface 1031 of the RDL 103;
S6: bonding a substrate 108 to the first surface 1031 of the RDL 103 and electrically connecting the substrate 108 to the RDL 103.

The method is further described below in conjunction with the accompanying drawings.

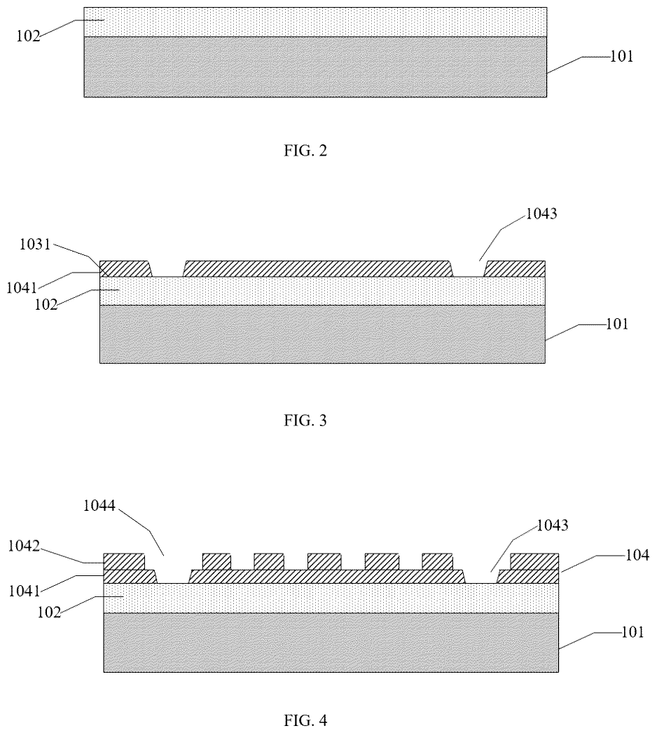

In step S1, referring to FIGS. 1 and 2, the temporary substrate 101 is first provided and the release layer 102 is formed on the temporary substrate 101.

Optionally, the temporary substrate 101 includes one of a silicon oxide substrate, a glass substrate, a ceramic substrate, a polymer substrate; and it may be round, square or in any other desired shape. Optionally, the release layer 102 includes a layer of light-to-heat conversion materials; the materials are capable of adhering to other components and will undergo denaturing and peeling off after laser irradiation.

Specifically, as an example, the temporary substrate 101 is a glass substrate; the glass substrate is inexpensive, the release layer can form easily on the surface of the glass substrate, and the subsequent peeling process is also simplified.

In step S2, referring to FIGS. 1, and 3 to 7, the method includes forming the RDL 103 on the release layer 102 using photosensitive dry film dielectric layers and the copper dual damascene process, wherein the RDL 103 includes the first sub RDL 104 and the second sub RDL 105 stacked on top of each other, the RDL 103 includes the first surface 1031 in contact with the release layer 102 and the second surface 1032 opposite to the first surface 1031.

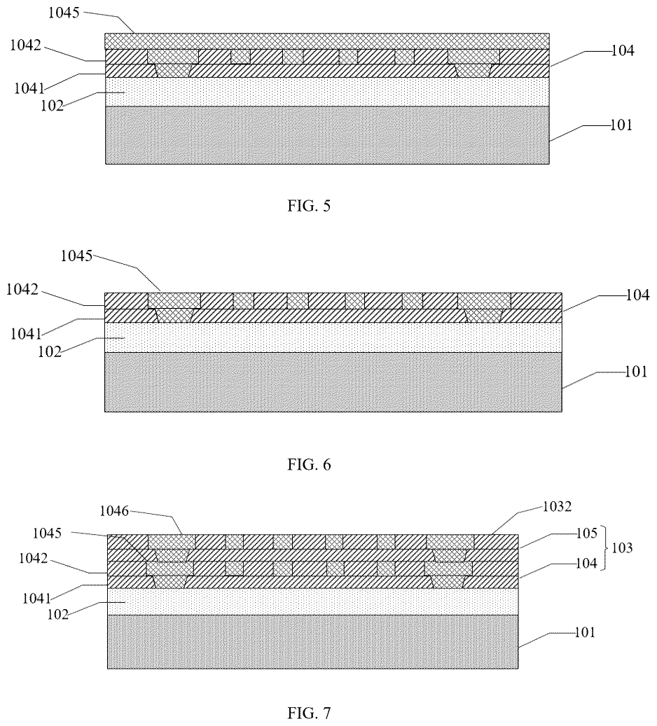

Specifically, as shown in FIG. 3, a first photosensitive dry film dielectric layer 1041 is first formed on the release layer 102, and first openings 1043 are formed by etching the temporary substrate 101 using the first photosensitive dry film dielectric layer 1041 as a mask. As shown in FIG. 4, a second photosensitive dry film dielectric layer 1042 is formed on the first photosensitive dry film dielectric layer 1041, and the second photosensitive dry film dielectric layer 1042 is etched to form second openings 1044 through the first openings 1043 using the second photosensitive dry film dielectric layer 1042 as a mask. A Ti/Cu seed layer (not shown) is then formed over the temporary substrate 101, wherein the Ti/Cu seed layer completely covers top surfaces of the second photosensitive dry film dielectric layer 1042, the first openings 1043 and the second openings 1044. That is, the intermediate structure as shown in FIG. 4 is coated with the Ti/Cu seed layer. A plating layer as shown in FIG. 5 is then formed by overfilling the first openings 1043 and the second openings 1044 above the Ti/Cu seed layer by an electroplating process; As shown in FIG. 6, after the second photosensitive dry film dielectric layer 1042, the first openings 1043, and the second openings 1044 have been overfilled, a planarization process may be performed to remove excess plating.

Optionally, a material of the plating layer includes one of copper, aluminum, nickel, gold, silver, and titanium. The plating layer may be formed by a deposition process such as electroplating.

Optionally, the planarization process may include one or more of grinding, chemical mechanical polishing (CMP), dry grinding, etching, and cutting. After planarization, the top surface of the second photosensitive dry film dielectric layer 1042 is substantially flush with the top surface of the plating.

Optionally, as shown in FIG. 7, the second sub RDL 105 is formed on the first sub RDL 104, wherein the first sub RDL 104 is electrically coupled to the second sub RDL 105, and steps for forming the second sub RDL 105 are the same as the steps for forming the first sub RDL 104.

Specifically, a first metal wiring portion 1045 is formed in the first sub RDL 104, a second metal wiring portion 1046 is formed in the second sub RDL 105, and the first metal wiring portion 1045 is electrically connected to the second metal wiring portion 1046 along a vertical direction.

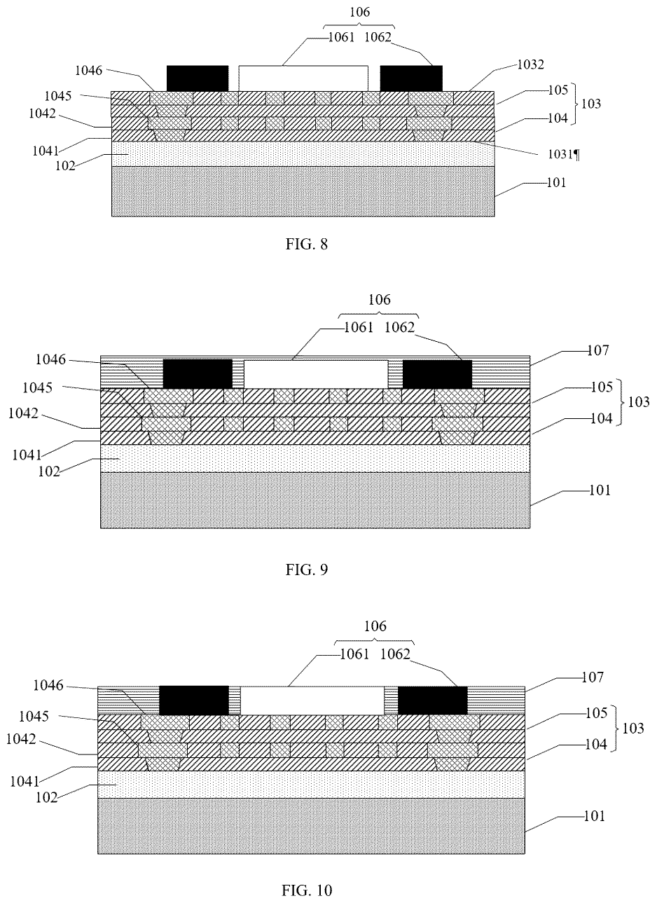

In step S3, referring to FIGS. 1 and 8, chips 106 are bonded to the second surface 1032 of the RDL 103, and the chips 106 are electrically connected to the RDL 103.

Optionally, the chips 106 includes a first chip 1061 and second chips 1062, and the second chips 1062 are symmetrically arranged on two sides of the first chip 1061; the first chip 1061 includes a logic chip, and the second chips 1062 include memory chips.

Optionally, the first chip 1061 and the second chips 1062 may be any existing semiconductor chip applicable to the package structure; for example, they may include a system chip, a logic chip, a memory chip such as a High-Bandwidth-Memory (HBM) chip.

Optionally, the second chips 1062 and the first chip 1061 are of different types, and the second chips 1062 are preferably symmetrically arranged on two sides of the first chip 1061 and electrically connected to the first sub RDL 103.

Specifically, as an example, the first chip 1061 is a logic (SOC) chip and the second chips 1062 are HBM chips and the second chips 1062 are symmetrically arranged on two sides of the first chip 1061. The first chip 1061 and the second chips 1062 may also be other types of chips.

In step S4, referring to FIGS. 1 and 9, the encapsulation layer 107 is formed, covering the chips 106 and the RDL 103.

Optionally, as shown in FIG. 9, the encapsulation layer 107 is formed by one of compression molding, transfer molding, liquid encapsulant curing, vacuum lamination, and spin coating. The encapsulation layer 107 includes one of an epoxy resin layer, a polyimide layer, and a silicone layer.

Optionally, as shown in FIG. 10, forming the encapsulation layer 107 is followed by performing a planarization process on the encapsulation layer 107 to expose top surfaces of the chips 106.

Specifically, the planarization process may include one or more of grinding, CMP, dry grinding, etching, and cutting. After the planarization process, the top surface of the encapsulation layer 107 is substantially flush with the top surfaces of the first chip 1061 and the second chips 1062.

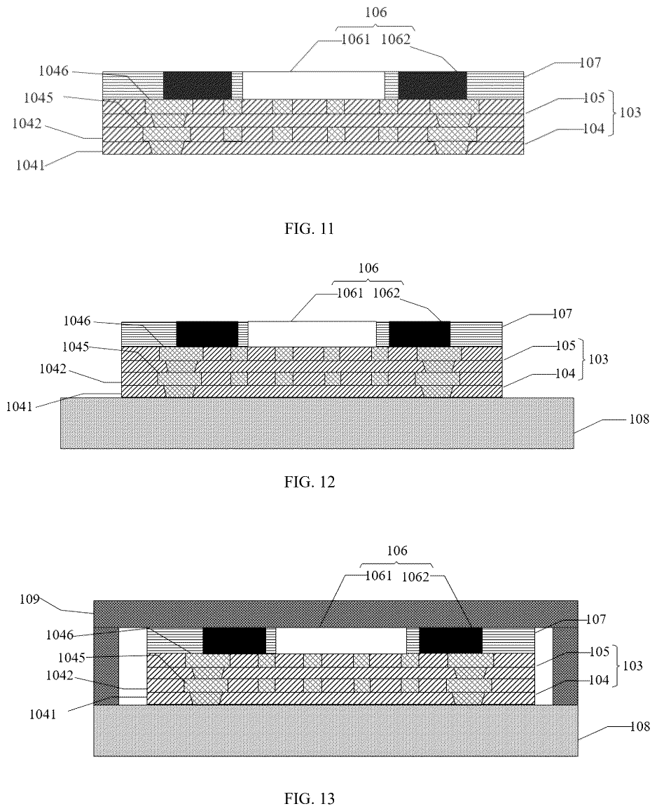

In step S5, referring to FIGS. 1 and 11, the temporary substrate 101 and the release layer 102 are removed to expose the first surface 1031 of the RDL.

Optionally, an array of metal bumps (not shown) are formed on the first surface 1031 of the RDL 103, and the metal bumps are electrically connected to the RDL 103.

Optionally, the metal bumps include one of gold-tin solder balls, silver-tin solder balls, and copper-tin solder balls.

Specifically, as an example, the metal bumps are copper-tin solder balls, which are formed by: first forming a copper-tin layer, and then using a high temperature reflow process to reflow the copper-tin layer into balls, and forming copper-tin solder balls after cooling down; or forming copper-tin solder balls by a ball-planting process.

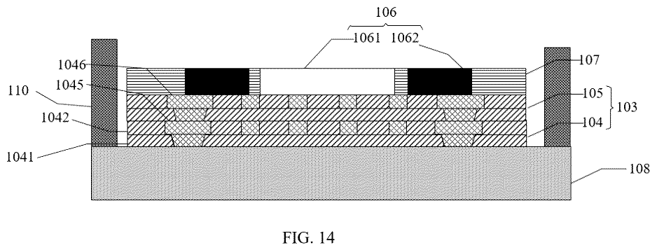

In step S6, referring to FIGS. 1 and 12, the substrate 108 is bonded to the first surface 1031 of the RDL 103 and electrically connected to the RDL 103.

Optionally, the substrate 108 includes one of a silicon oxide substrate, a glass substrate, a ceramic substrate, a polymer substrate, and the substrate 110 is electrically coupled to the RDL 103 by the metal bumps.

Further, referring to FIGS. 13 and 14, a heat sink cover 109 may be formed over the substrate 108, or a reinforcing member 110 may be formed over the substrate 108.

Optionally, as shown in FIG. 13, the heat sink cover 109 is formed over the substrate 108, and the heat sink cover 109 covers the encapsulation layer 107, the chips 106 and the RDL 103.

Optionally, the heat sink cover 109 is metal or ceramic, and the heat sink cover 109 is mechanically connected to the substrate 108.

Specifically, bonding members (not shown) are formed at the peripheral of the substrate 110, and the heat sink cover 109 and the substrate 108 are connected by the bonding members.

As shown in FIG. 14, as an example, the reinforcing member 110 is formed over the substrate 110 and mechanically connected to the substrate 108, and the reinforcing member 110 has a height taller than a surface of the encapsulation layer 107.

### Embodiment 2

As shown in FIGS. 8-10, 13 and 14, Embodiment 2 provides an integrated circuit package structure, including: a substrate 110; an RDL 103, which has a first surface 1031 in contact with the substrate 108 and a second surface 1032 opposite to the first surface 1031, wherein the RDL 103 is made of photosensitive dry film dielectric layers, and the RDL 103 includes a first sub RDL 104 and a second sub RDL 105 stacked on top of each other; chips 106, disposed over the second surface 1032 of the RDL 103 and electrically connected to the RDL 103; an encapsulation layer 107, covering the chips 106 and the RDL 103.

Optionally, as shown in FIG. 5, the first sub RDL 104 has a thickness ranging from 1 to 20 μm; for example, it may be 1 μm, 5 μm, 10 μm, or 20 μm.

Optionally, as shown in FIG. 7, the second sub RDL 105 has a thickness ranging from 1 to 20 μm; for example, it may be 1 μm, 5 μm, 10 μm, or 20 μm.

Optionally, as shown in FIGS. 6 and 7, a first metal wiring portion 1045 is formed in the first sub RDL 104, a second metal wiring portion 1046 is formed in the second sub RDL 105, and the first metal wiring portion 1045 is electrically connected to the second metal wiring portion 1046 along a vertical direction.

Optionally, as shown in FIGS. 13 and 14, the package structure further includes a heat sink cover 109 formed over the substrate 108, wherein the heat sink cover 109 encloses the encapsulation layer 107 and is mechanically connected to the substrate 108; or the package structure further includes a reinforcing member 110 formed over the substrate 108, wherein the reinforcing member 110 has a height taller than a surface of the encapsulation layer 107 and is mechanically connected to the substrate 108.

In summary, the present disclosure provides an integrated circuit package structure and a manufacturing method of the same; the integrated circuit package structure includes: a substrate; an RDL, including a first surface in contact with the substrate and a second surface opposite to the first surface, wherein the RDL is made of photosensitive dry film dielectric layers, and the RDL includes a first sub RDL and a second sub RDL stacked on top of each other; an encapsulation layer, covering the chips and the RDL. The plurality of chips with different functions are integrated in a single package structure, thereby improving the integration of the package; the adoption of high-resolution dry film polymer to form a finer RDL structure increases the bandwidth of the final device and decreases inter-chip delay; high-density wiring capability is achieved without TSV-containing interposers, thus lowering production cost. Therefore, the present disclosure effectively overcomes various shortcomings in the existing technology and has high industrial utilization value.

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

1. A manufacturing method of an integrated circuit package structure, comprising:
forming a release layer on a temporary substrate;
forming an RDL on the release layer, wherein the RDL comprises a first sub RDL and a second sub RDL stacked on top of each other; forming photosensitive dry film dielectric layers and a copper layer from dual damascene process in the RDL, wherein the RDL has a first surface in contact with the release layer and a second surface opposite to the first surface;
bonding chips to the second surface of the RDL, wherein the chips are electrically connected to the RDL;
forming an encapsulation layer covering the chips and the RDL;
removing the temporary substrate and the release layer to reveal the first surface of the RDL; and
bonding a substrate to the first surface of the RDL and electrically connecting the substrate to the RDL.

1. The manufacturing method according to claim 1, wherein the first sub RDL is formed by:
forming a first photosensitive dry film dielectric layer over the release layer, photo-etching the first photosensitive dry film dielectric layer to form first openings;
forming a second photosensitive dry film dielectric layer over the first photosensitive dry film dielectric layer, photo-etching the second photosensitive dry film dielectric layer to form second openings, and the second openings are communicated with the first openings;
forming a Ti/Cu seed layer over the second photosensitive dry film dielectric layer, the first openings, and the second openings; and
forming a plating layer over the Ti/Cu seed layer through electroplating and planarizing the plating layer.

2. The manufacturing method according to claim 1, wherein a first metal wiring portion is formed in the first sub RDL, a second metal wiring portion is formed in the second sub RDL, and the first metal wiring portion is electrically connected to the second metal wiring portion along a vertical direction.

3. The manufacturing method according to claim 1, further comprising forming a heat sink cover over the substrate or forming a reinforcing member over the substrate.

4. The manufacturing method according to claim 1, wherein the chips comprise a first chip and second chips, and the second chips are symmetrically arranged on two sides of the first chip, wherein the first chip comprises a logic chip, and the second chips comprise memory chips.

5. The manufacturing method according to claim 1, wherein after forming the encapsulation layer, planarizing the encapsulation layer to expose top surfaces of the chips.

6. An integrated circuit package structure, comprising:
a substrate;
an RDL, having a first surface in contact with the substrate and a second surface opposite to the first surface, wherein the RDL comprises a first sub RDL and a second sub RDL stacked on top of each other, and the RDL comprises photosensitive dry film dielectric layers;
chips, wherein the chips are disposed over the second surface of the RDL and electrically connected to the RDL; and
an encapsulation layer, covering the chips and the RDL.

7. The integrated circuit package structure according to claim 7, wherein a thickness of the first sub RDL ranges from 1 to 20 μm and a thickness of the second sub RDL ranges from 1 to 20 μm.

8. The integrated circuit package structure according to claim 7, wherein a first metal wiring portion is formed in the first sub RDL, a second metal wiring portion is formed in the second sub RDL, and wherein the first metal wiring portion is electrically connected to the second metal wiring portion along a vertical direction.

9. The integrated circuit package structure according to claim 7, further comprising: a heat sink cover over the substrate, wherein the heat sink cover covers the encapsulation layer and is mechanically connected to the substrate; wherein the heat sink cover is formed on a reinforcing member over the substrate, wherein the reinforcing member has a height taller than a surface of the encapsulation layer and is mechanically connected to the substrate.
